(19) United States
(12) Patent Application Publication
(10) Pub. No.: US 2005/0170293 A1
(43) Pub. Date: Aug. 4, 2005

(54) Exposure apparatus

(76) Inventor: Sang Jin Kim, Seoul (KR)

Correspondence Address: MCKENNA LONG & ALDRIDGE LLP, 1900 K STREET, NW, WASHINGTON, DC, 20006, US

(21) Appl. No.: 11/041,213

(22) Filed: Jan. 25, 2005

(30) Foreign Application Priority Data
Feb. 2, 2004 (KR) 2004-06705

(51) Int. Cl. G03F 9/00; G03C 5/00; G03B 27/42

(52) U.S. Cl. 430/321; 355/53

(57) ABSTRACT

An exposure apparatus includes a glass moving in a predetermined direction on a stage, a roll-film mask positioned above the glass and having a transfer pattern therein, and an exposure system for radiating ultraviolet light on an upper surface of the film mask so that the transfer patter formed in the film mask is transferred on the glass.

This application claims the benefit of Korean Patent Application No. 2004-06705 filed in Korea on Feb. 2, 2004, which is hereby incorporated by reference in its entirety.

### BACKGROUND OF THE INVENTION

1. Field of the Invention

The present invention relates to an exposure apparatus, and more particularly to a scan-type exposure apparatus that is not restricted by mask size and also low cost.

2. Description of the Related Art

Generally, an exposure apparatus is a semiconductor device that conducts the exposure process in photolithography, and the exposure is a critical process for such products as PDP, LCD semiconductors, which transfer a mask pattern onto a glass.

Photolithography includes a wafer rinsing process for removing impurities adhered to the wafer surface before the photo process, a surface treatment process for treating a surface of the wafer so that a photosensitive film may be adhered to the wafer better, a photosensitive film coating process for uniformly coating a photosensitive film to the wafer by a desired thickness, an alignment/exposure process for positioning a mask on the wafer coated with the photosensitive film and exposing the mask to light so that a circuit depicted in the mask is formed on the wafer, and a developing process for removing the photosensitive film transformed by exposure with a rinsing agent.

The exposure apparatus includes a light source system for supplying light to the mask, a luminous system for dispersing the light emitted from the light source into a regular surface light source and focusing it to a certain size, a mask (or, a reticle) in which a circuit pattern to be formed on the wafer is designed, an alignment system for aligning the mask and the wafer to desired positions, and a lens system for making the light through the mask to be formed at a desired position of the wafer.

Various displays are used currently including cathode ray tube (CRT), liquid crystal display (LCD), electroluminescence (EL), plasma display panel (PDP). In particular, an LCD is used for computer monitors, notebooks and personal portable terminals due to its low energy consumption, full-color, and light/thin/short/small characteristics which are better than other displays having the same size. The LCD is even used for TVs and monitors for airplanes.

The LCD is a flat display, and uses a flat glass as its material. In addition, most LCDs in the market use thin film transistors that are produced through a procedure similar to a semiconductor manufacturing process. Here, the process of producing the thin film transistors requires several masks and with the same number of exposure processes.

The exposure system is generally designed to be suitable for a size of an initially-designed glass substrate, and usually its exposure region cannot be changed. In addition, the exposure process employs bundle exposure, partition exposure and scan exposure, and is classified into a contact type, a proximity type and a projection type depending on an interval property of the mask and the wafer.

The bundle exposure aligns a glass and a mask with a pattern, and then exposes the entire surface of the glass at one time with the use of parallel ultraviolet light with an area corresponding to the glass. The bundle exposure has a disadvantage in that it is difficult to manufacture a mirror for making parallel ultraviolet light with an area corresponding to the glass as the size of glass is greatly increased. In addition, a size of a machine used for manufacture of the glass is too large, and the cost of optical components are also increasing. Moreover, there is a limit to making a mask corresponding to the glass size, and the mask also becomes very expensive as the mask size is increased. Thus, the bundle exposure is difficult to use if the glass is larger than a certain size.

In order to solve such problems, the partition exposure and the scan exposure have been proposed.

The partition exposure partitions a large glass into several parts, and then exposes a piece of the glass with a small mask by changing a position of the mask several times. In this case, the mask is small, but the alignment between the glass and the mask is very difficult since the exposure process must be conducted several times. In addition, the system becomes complicated, and the equipment for this process is very expensive.

FIG. 1 shows a related art scan-type exposure apparatus. Referring to FIG. 1, a mask 102 is positioned on a glass 101 with a narrow ultraviolet light. The front ends of the glass 101 and the mask 102 are aligned, and their entire areas are exposed to light by moving (or, scanning) the mask 102 and the glass 101 simultaneously.

However, this manner of scanning also has a problem in that it requires a mask having a size as great as the glass, similar to the bundle exposure.

When such a scan-type exposure system 110 is used, the size of the glass that may be exposed to light is limited by the size of the mask as the mask size is increased. In addition, as the mask size is increased, the mask becomes more expensive. Moreover, if the mask has a large size, it is more dangerous for the operator in handling the mask.

### SUMMARY OF THE INVENTION

Accordingly, the present invention is directed to exposure apparatus that substantially obviates one or more of the problems due to limitations and disadvantages of the related art.

The present invention is designed to solve the above problems of the prior art, and has an advantage of providing an exposure apparatus with a very competitive price by utilizing a low cost mask to a scan-type exposure apparatus.

Another advantage of the invention is to provide a scan-type exposure apparatus using a film mask with a pattern to be transferred on the glass, wherein the film mask is wound on a type of a roll, and then moved so as to scan the entire area after the film mask and the glass are aligned.

In order to accomplish the above, the present invention provides an exposure apparatus, including a glass moving in a predetermined direction on a stage; a roll-type film mask positioned above the glass and having a transfer pattern therein; and an exposure system for radiating ultraviolet light on an upper surface of the film mask so that the transfer pattern formed in the film mask is transferred on the glass.

In another aspect of the invention, there is also provided an exposure apparatus, including a glass moving in a predetermined direction; a film mask formed above the glass and having a transfer pattern therein; a first roll around which one end of the film mask is wound; a second roll around which another end of the film mask is wound; and an exposure system for scanning a region of the film mask between the first roll and the second roll by exposing ultraviolet light onto the film mask.

By using the above configuration, the exposure apparatus may have a very competitive price since a low cost film mask is used instead of an expensive photo-mask made of glass or quartz.

In addition, since the mask with a pattern to be transferred onto the glass is used, which is wound in a roll, the related art problem where the mask size restricts the size of glass is eliminated.

Moreover, by using the exposure apparatus of the present invention, an operator may easily handle even a large glass since the operator just handles the rolls of the mask.

Furthermore, whereas the tension of the film mask was not easily controlled in the prior art, the tension of the film mask is easily controlled in the present invention since the ultraviolet light is used just in a narrow region, so the film does not droop.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 illustrates a related art scan-type exposure apparatus; and

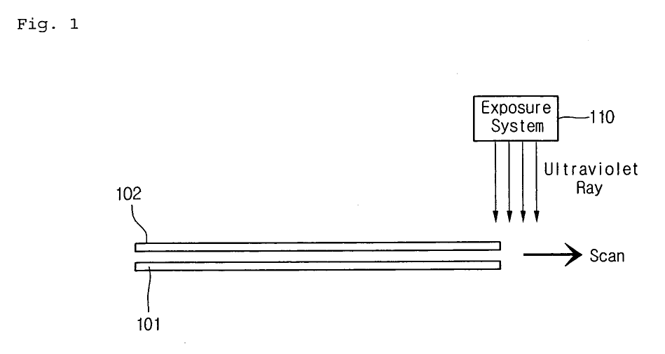

FIG. 2 illustrates a scan-type exposure apparatus using a film mask according to the present invention.

### DETAILED DESCRIPTION OF THE INVENTION

Reference will now be made in detail to an embodiment of the present invention, example of which is illustrated in the accompanying drawings. However, the spirit of the invention is not limited to the embodiment, but retrograde embodiments and other embodiments within the scope of the invention may be easily proposed by adding, changing or deleting any component.

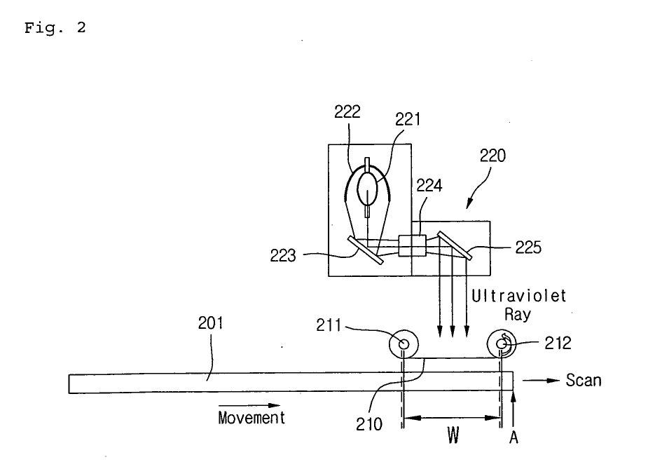

FIG. 2 illustrates a scan-type exposure apparatus using a film mask according to an embodiment of the present invention.

Referring to FIG. 2, the scan-type exposure apparatus of the present invention includes a glass 201 on which a set pattern is transferred while the glass 201 is moved to a certain direction on a stage, a mask 210 wound in a roll with a pattern to be transferred on the glass 201, a first roll 211 around which the mask 210 is wound, a second roll 212 spaced apart from the first roll 211 by a predetermined distance and around which the mask 210 that was released by rotation of the first roll 211 is wound, and an exposure system 220 for vertically radiating light to an upper surface of the mask 210. In addition, a driving system (not shown) for driving the first roll 211, the second roll 212 and the glass 201 is further included so as to make the mask 210 and the glass 201 move at the same speed.

The exposure system 220 includes a light source 221 for emitting ultraviolet light, a reflection plate 222 for reflecting the ultraviolet light emitted from the light source 221 to one direction, a first reflective mirror 223 for reflecting again the ultraviolet light to a predetermined direction, which was already reflected by the reflection plate 222, a slit 224 for allowing the ultraviolet light reflected by the first reflective mirror 223 to pass through, and a second reflective mirror 225 for reflecting again the ultraviolet light passing through the slit 224 to a predetermined direction so as to be radiated on the upper surface of the mask 210.

The operation of the scan-type exposure apparatus using a film mask configured as mentioned above according to the present invention is now described with reference to the attached drawing.

First, the glass 201 with a certain size is placed on a stage (not shown). The mask 210 uses a film mask made of a low cost film. The scan exposure is selected as the exposure type.

The mask 210 wound around the first roll 211 is aligned above the glass 201. At this time, a front end of the glass 201 is aligned with a front end of the mask 210. In addition, a pattern to be transferred on the glass 201 is formed in the mask 210 that is wound around the first roll 211. Then, the mask 210 is released by means of rotation of the first roll 211, and the released mask 210 is wound around the second roll 212. Here, the first roll 211 and the second roll 212 are rotated at a suitable speed so that the mask 210 is tightly spread with a certain tension.

If a film is used for such a mask, the film may have a tendency to droop down or not tightly spread. Thus, in order to solve this problem, the ultraviolet light radiated from the exposure system 220 may be applied in a narrow region (W), such that the actual region of the mask applied with the ultraviolet light is narrow. Thus, the film mask tension may be easily controlled.

In addition, since the mask 210 has a film roll shape that is wound around the first roll 211 and the second roll 212, the related art problem where the mask size restricts or limits the size of glass is eliminated.

Meanwhile, the mask 210 and the glass 201 are synchronized. For example, they may move in the same direction at the same speed, and the first and second rolls 211 and 212 rotate in the same direction so that the first roll 211 unwinds the film mask and the second roll 212 winds the released film mask.

In addition, the exposure system 220 is positioned, for example, above the film mask 210. When the ultraviolet light is emitted from the light source 221, the exposure system 220 reflects the ultraviolet light by means of the reflection plate 222 surrounding the light source 221 so that the ultraviolet light is focused forward. Then, the first reflective mirror 223 reflects the incident light toward the slit 224, and the reflected light is selectively passed through the slit 224. Then, the ultraviolet light selectively passing through the slit 224 is reflected by the second reflective mirror 225 so as to be radiated downward through the mask 210, where the film mask region (W) is formed.

After front portion (A) of the glass 201 and the mask 210 placed on the stage are aligned, the driving system drives the first and second rolls 211 and 212 together with the glass 210. At this time, the mask 210 wound around the rolls 211 and 212 is moved synchronously with the glass 201, for example, in the same direction at the same speed as the glass 201.

Accordingly, the mask 210 wound around the first roll 211 is released and then wound around the second roll 212 as mentioned above, and the exposure region of the mask 210 passes above the glass 201.

At this time, the light emitted from the light source 221 of the scan-type exposure system 220 is vertically transmitted downward via the first reflective mirror 223, the slit 224 and the second reflective mirror 225 corresponding to a light path, similarly to the former case. In addition, the transmitted ultraviolet light is exposed so that the pattern formed in the mask 210 is transferred onto the glass 201. In this way, a desired pattern may be transferred on the entire area of the moving glass 201 as the first roll 211 unwinds the mask 210 and the second roll 212 winds the mask 210.

While it is difficult and cumbersome an operator to handle a large mask in the related art, the exposure apparatus of the present invention is very easy to operate since, for example, the operator simply handles the rolls 211 and 212 of the film mask 210.

It will be apparent to those skilled in the art that various modifications and variation can be made in the present invention without departing from the spirit or scope of the invention. Thus, is it intended that the present invention cover the modifications and variations of this invention provided they come within the scope of the appended claims and their equivalents.

1. An exposure apparatus, comprising:
a glass moving in a predetermined direction on a stage;
a roll-type film mask spaced from the glass and having a transfer pattern; and
an exposure system for radiating ultraviolet light on a surface of the film mask, the transfer pattern of the film mask being transferred onto the glass.

2. The exposure apparatus according to claim 1, wherein the film mask is supported by a first roll around which one end of the film mask is wound and a second roll for winding the film mask unwound from the first roll.

3. The exposure apparatus according to claim 1, further comprising a driving system for driving the glass and the film mask to be synchronously moved.

4. The exposure apparatus according to claim 1, further comprising a driving system for driving the glass and the film mask to be moved at substantially the same speed.

5. The exposure apparatus according to claim 2, further comprising a driving system for controlling the film mask to maintain a predetermined tension between the first roll and the second roll.

6. The exposure apparatus according to claim 1, wherein the exposure system is a scan-type exposure system that scans a region of the film mask by a vertically emitted light.

7. The exposure apparatus according to claim 1, wherein the roll-type film mask is positioned above the glass and the ultraviolet light is radiated on an upper surface of the film mask.

8. An exposure apparatus, comprising:
a glass moving in a predetermined direction;
a film mask spaced from the glass and having a transfer pattern;
a first roll around which one end of the film mask is wound;
a second roll around which another end of the film mask is wound; and
an exposure system for scanning a region of the film mask between the first roll and the second roll by transmitting ultraviolet light to the film mask.

9. The exposure apparatus according to claim 8, wherein the exposure system includes:
a light source for emitting ultraviolet light;
a reflection plate for focusing the ultraviolet light emitted from the light source to one direction; and
reflective mirror system for reflecting the ultraviolet light focused by the reflection plate and transmitting the ultraviolet light to the film mask.

10. The exposure apparatus according to claim 9, wherein the reflective mirror system include:
a first reflective mirror for reflecting the ultraviolet light focused by the reflection plate to a predetermined direction; and
a second reflective mirror for reflecting again the ultraviolet light reflected by the first reflective mirror to transmit the ultraviolet light to the film mask.

11. The exposure apparatus according to claim 10, further comprising a slit provided between the first and second reflective mirrors and selectively passing the light reflected by the first reflective mirror through the slit.

12. The exposure apparatus according to claim 8, wherein rotation speeds of the first and second rolls are controlled to maintain a predetermined tension of the film mask.

13. The exposure apparatus according to claim 8, further comprising a driving system for driving the film mask between the first and second rolls to be synchronously moved with the glass.

14. The exposure apparatus according to claim 8, further comprising a driving system for driving the film mask between the first and second rolls to be moved at substantially the same speed as the glass.

15. A method of making a display device using an exposure apparatus comprising:
providing a substrate moving in a predetermined direction on a stage;
providing a roll-type film mask spaced from the substrate and having a transfer pattern; and
exposing ultraviolet light on a surface of the film mask, the transfer pattern of the film mask being transferred onto the substrate.

16. The method of claim 15, wherein the display device is a plasma display panel.

17. The method of claim 15, wherein the display device is a liquid crystal display.

18. The method of claim 15, wherein the display device is a electroluminescent device.

19. A method of making a display device using an exposure apparatus comprising:
providing a substrate moving in a predetermined direction;
positioning a film mask spaced from the glass and having a transfer pattern;
providing a first roll around which one end of the film mask is wound;
providing a second roll around which another end of the film mask is wound; and
exposing ultraviolet light to a region of the film mask between the first roll and the second roll.

20. The method of claim 15, wherein the display device is a plasma display panel.

21. The method of claim 15, wherein the display device is a liquid crystal display.

22. The method of claim 15, wherein the display device is a electroluminescent device.
